(19) United States
(12) Patent Application Publication
(10) Pub. No.: US 2016/0294320 A1
(43) Pub. Date: Oct. 6, 2016

(54) SOLAR CELL MODULE TERMINAL BOX

(71) Applicant: Panasonic Intellectual Property Management Co., Ltd., Osaka (JP)

(72) Inventor: Yasutoshi MORI, Osaka (JP)

(73) Assignee: Panasonic Intellectual Property Management Co., Lt d., Osaka (JP)

(21) Appl. No.: 15/182,606

(22) Filed: Jun. 15, 2016

Related U.S. Application Data
(63) Continuation of application No. PCT/JP2014/081054, filed on Nov. 25, 2014.

(30) Foreign Application Priority Data
Dec. 19, 2013 (JP) 2013-262451

(51) Int. Cl. H02S 40/34; H01L 31/02; H01L 31/068

(52) U.S. Cl. CPC H02S 40/34; H01L 31/0684; H01L 31/02021

(57) ABSTRACT

A solar cell module terminal box to be attached to a solar cell module is provided. The solar cell module terminal box includes: a connecting terminal which electrically connects a connecting line extending from the solar cell module, to a cable for external connection routed out from the solar cell module; a terminal box main body including an attaching wall portion to which the connecting terminal is attached; and a cover which closes the terminal box main body. The connecting terminal includes: a base portion that is attached to the attaching wall portion; a leg portion which extends upwardly from the base portion, away from the attaching wall portion; a connecting portion which extends continuously from the leg portion and to which the connecting line is soldered; and a linear protrusion disposed at each end of the connecting portion to deter solder from flowing out to the leg portion.

### CROSS REFERENCE TO RELATED APPLICATION

This application is a U.S. continuation application of PCT International Patent Application Number PCT/JP2014/081054 filed on Nov. 25, 2014, claiming the benefit of priority of Japanese Patent Application Number 2013-262451, filed on Dec. 19, 2013, the entire contents of which are hereby incorporated by reference.

### TECHNICAL FIELD

The present disclosure relates to a solar cell module terminal box.

### BACKGROUND ART

A solar cell module is generally provided with a terminal box for connecting a connecting line extending from a solar cell to a cable for external connection (Patent Literature 1: Japanese Unexamined Patent Application Publication No. 2011-155216, etc). The connecting line extending from the solar cell is soldered to a connecting terminal provided inside the terminal box.

### SUMMARY

Attempts to miniaturize the terminal box have faced a problem that a soldering iron comes into contact with a resin portion of the terminal box, leading to melting of the resin portion. Furthermore, there has been a problem that solder flows out from the connecting terminal.

An object of the present disclosure is to provide a solar cell module terminal box capable of deterring solder from flowing out from a connecting terminal.

A solar cell module terminal box according to the present disclosure is a solar cell module terminal box to be attached to a solar cell module. The solar cell module terminal box includes: a connecting terminal which electrically connects a connecting line extending from the solar cell module, to a cable for external connection routed out from the solar cell module; a terminal box main body including an attaching wall portion to which the connecting terminal is attached; and a cover which closes the terminal box main body. The connecting terminal includes: a base portion that is attached to the attaching wall portion; a leg portion which extends upwardly from the base portion, away from the attaching wall portion; a connecting portion which extends continuously from the leg portion and to which the connecting line is soldered; and a linear protrusion disposed at each end of the connecting portion to deter solder from flowing out to the leg portion.

With the present disclosure, it is possible to deter solder from flowing out from a connecting terminal.

### BRIEF DESCRIPTION OF THE DRAWINGS

The figures depict one or more implementations in accordance with the present teaching, by way of examples only, not by way of limitations. In the figures, like reference numerals refer to the same or similar elements.

FIG. 1 is a plan view illustrating a front surface of a solar cell module to which a terminal box is attached.

FIG. 2 is an enlarged plan view illustrating a rear surface of the solar cell module to which the terminal box is attached.

FIG. 3 is a plan view illustrating an inside of the terminal box according to an embodiment.

FIG. 4 is an enlarged plan view illustrating a connecting terminal of the terminal box according to the embodiment.

FIG. 5 is a cross-sectional view taken along the line V-V illustrated in FIG. 4.

FIG. 6 is a cross-sectional view illustrating a state in which a resin is filled in the terminal box and a cover is attached, after a connecting line is soldered to the connecting terminal.

### DETAILED DESCRIPTION

The following describes an embodiment. The embodiment described below is merely an example, and the present disclosure is not limited to the embodiment described below. In each of the diagrams, components having substantially the same function are assigned with the same reference signs, and there are instances where redundant descriptions are omitted or simplified.

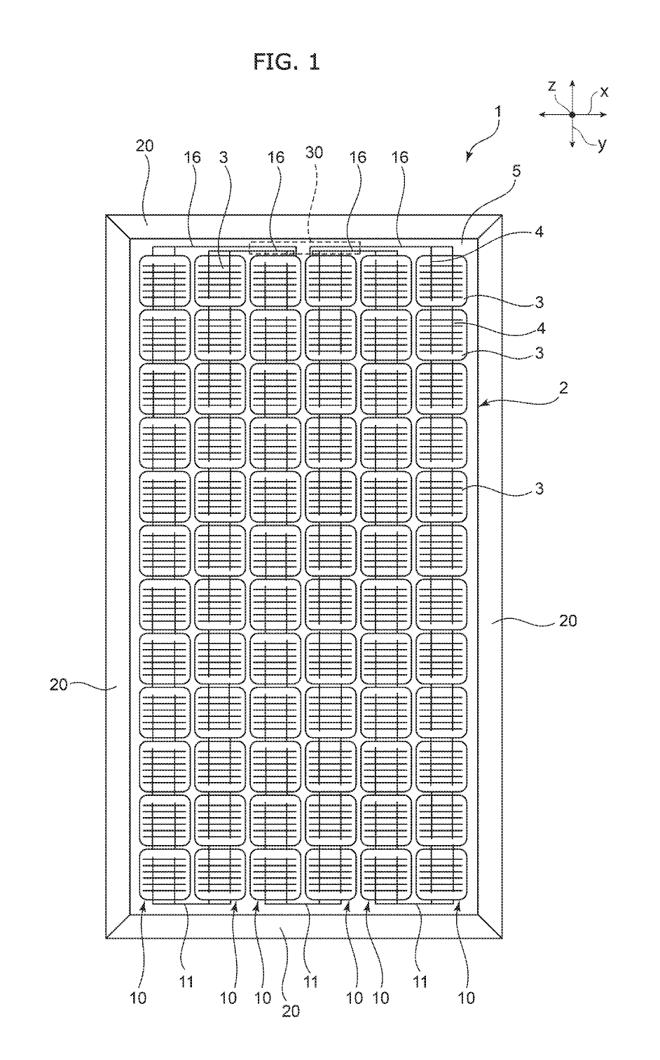

FIG. 1 is a plan view illustrating a front surface of a solar cell module to which a terminal box is attached. As illustrated in FIG. 1, a solar cell module 1 includes a plurality of solar cells 3. The solar cells 3 are solar cells in each of which a crystalline silicon substrate such as a monocrystalline silicon substrate and a polycrystalline silicon substrate is employed. According to the embodiment, a solar cell is employed in which a substantially intrinsic amorphous silicon layer is disposed between the monocrystalline silicon substrate and an amorphous silicon layer, thereby reducing a defect in the interface and improving the characteristics of a heterojunction interface.

The solar cells 3 aligned in a y axis direction are electrically connected between adjacent ones of the solar cells 3 via interconnecting lines 4. The solar cells 3 electrically connected via the interconnecting lines 4 form solar cell strings 10. The solar cell strings 10 are arranged in an x axis direction and electrically connected via connecting wires 11 disposed at one end of the solar cell strings 10. The solar cell strings 10 are connected to output wires 16 at the other end of the solar cell strings 10. The solar cell panel 2 includes a plurality of the solar cell strings 10 electrically connected via the connecting wires 11 and the output wires 16.

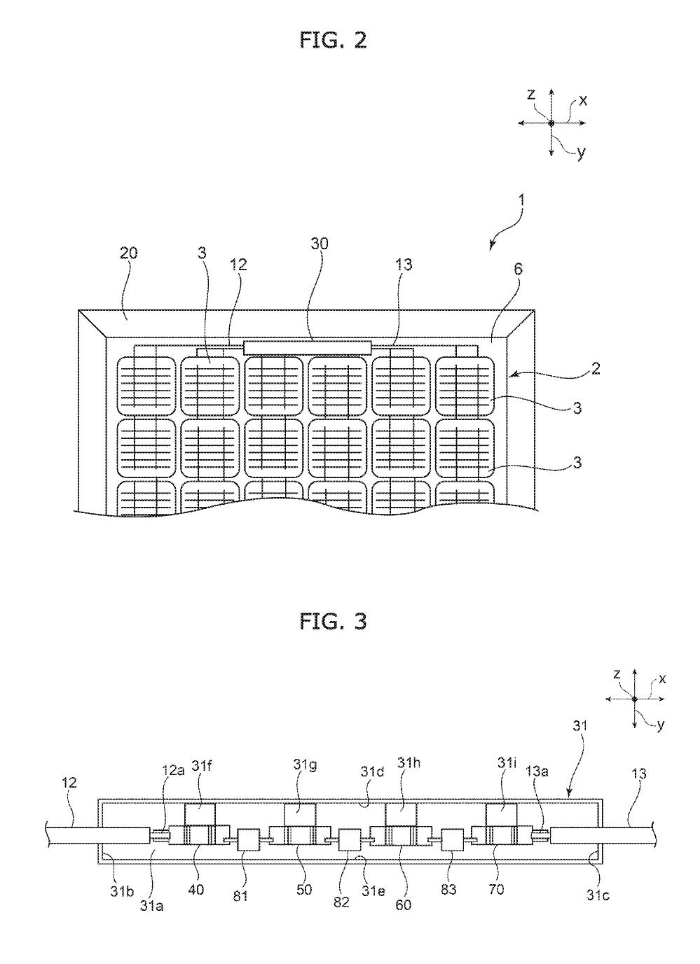

A frame 20 is secured around the solar cell panel 2. According to the embodiment, the solar cell module 1 is a bifacial solar cell module. Accordingly, the terminal box 30 is attached to a region between the frame 20 and the solar cells 3, so as to avoid interfering with light reception of the solar cells 3. In addition, the terminal box 30 has a substantially rectangular shape which is horizontally long and extends in the x direction, so as to be attached to the region between the frame 20 and the solar cells 3. The terminal box 30 is attached on a front surface 5 and a rear surface 6 (see FIG. 2) opposite to the front surface 5.

FIG. 2 is an enlarged plan view illustrating a back surface of the solar cell module to which the terminal box is attached. As illustrated in FIG. 2, the terminal box 30 is attached on the rear surface 6 of the solar cell module 1. Connecting lines extending from the output wires 16 are routed into the terminal box 30, and the connecting lines are each electrically connected inside the terminal box 30 to cables for external connection 12 and 13 which are routed out from the solar cell module 1.

FIG. 3 is a plan view illustrating the inside of a terminal box main body according to the embodiment. As illustrated in FIG. 3, the terminal box main body 31 includes a bottom surface 31a and side surfaces 31b to 31e which are formed continuously with the bottom surface 31a. These portions are formed of a resin. The bottom surface 31a includes through-holes 31f to 31i for routing the connecting lines extending from the output wires 16 into the terminal box main body 31. The connecting lines routed into the terminal box main body 31 are electrically connected to connecting terminals 40, 50, 60, and 70. A diode 81, a diode 82, and a diode 83 are connected between the connecting terminals 40 and 50, between the connecting terminals 50 and 60, and the connecting terminals 60 and 70, respectively.

A core line 12a of the cable for external connection 12 is attached to the connecting terminal 40 disposed at one end of the terminal box main body 31, by a physically securing method such as crimping. A core line 13a of the cable for external connection 13 is attached to the connecting terminal 70 disposed at the other end of the terminal box main body 31, by a physically securing method such as crimping.

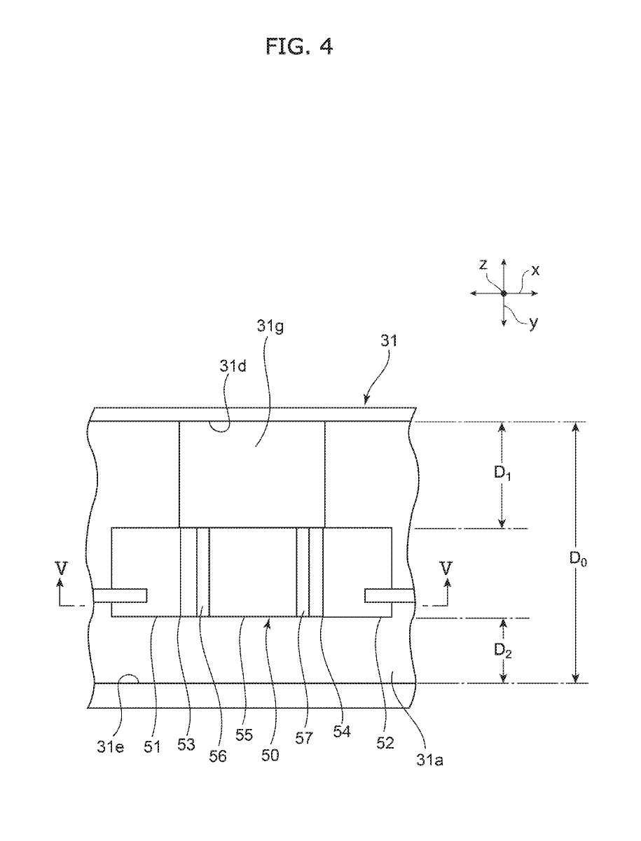

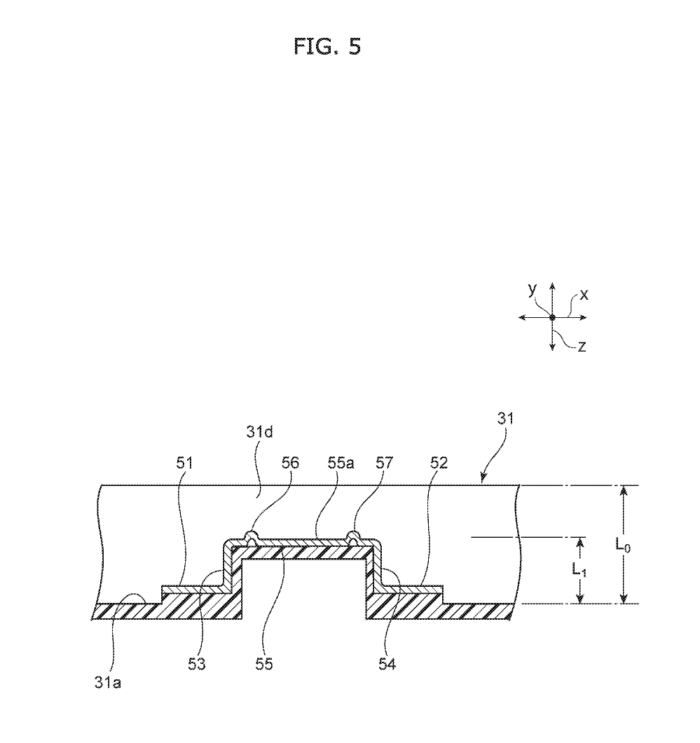

FIG. 4 is an enlarged plan view illustrating the connecting terminal of the terminal box according to the embodiment. FIG. 5 is a cross-sectional view taken along the line V-V illustrated in FIG. 4. As illustrated in FIG. 4 and FIG. 5, the connecting terminal 50 is attached to the terminal box main body 31, by attaching base portions 51 and 52 to the base surface 31a that is an attaching wall portion. The connecting terminal 50 includes leg portions 53 and 54 which extend upwardly from the base portions 51 and 52, away from the bottom surface 31a that is the attaching wall portion. A connecting portion 55 is formed to extend continuously from the leg portions 53 and 54 and substantially parallel to the bottom surface 31a. The connecting portion 55 has an upper surface 55a to which the connecting line is soldered. Linear protrusions 56 and 57 for deterring solder from flowing out to the leg portions 53 and 54 are disposed at the ends of the connecting portion 55.

Each of the other connecting terminals 40, 60, and 70 has substantially the same configuration as the connecting terminal 50. The following describes the connecting terminal 50, and the description of the connecting terminal 50 holds true for the other connecting terminals 40, 60, and 70.

As described above, the connecting terminal 50 includes the connecting portion 55 which extends continuously from the leg portions 53 and 54 that extend upwardly from the base portions 51 and 52, and to which the connecting line is soldered. Accordingly, even when a soldering iron is applied at an angle, it is possible to solder the connecting line to the connecting portion 55 while avoiding contact with a resin portion such as the side surfaces 31d and 31e of the terminal box main body 31. In addition, since the linear protrusions 56 and 57 are formed at the ends of the connecting portion 55, it is possible to deter solder from flowing out from the connecting portion 55 when soldering is performed.

As illustrated in FIG. 4, the connecting terminal 50 is disposed at a location a distance D₁ away from the side surface 31d of the terminal box main body 31 and a distance D₂ away from the side surface 31e of the terminal box main body 31. Each of the other connecting terminals 40, 60, and 70 is disposed in the same manner as the connecting terminal 50. The distance D₂ is greater than or equal to one mm, for example. By setting the distance D₂ within such a range, even when a filler resin which will be described later comes off the bottom surface 31a and the side surfaces 31b to 31e of the terminal box main body 31, it is possible to cover the connecting terminals 40 to 70 with the filler resin, making it possible to deter infiltration of moisture from outside. Accordingly, it is possible to maintain a high moisture resistance property for a long period of time.

As illustrated in FIG. 5, the leg portions 53 and 54 are formed such that the upper surface 55a of the connecting portion 55 of the connecting terminal 50 has a height L₁ from the bottom surface 31a of the terminal box main body 31. The height L₁ is, for example, in a range from one-third to four-fifths of a height L₀ that is an inside height of the terminal box main body 31.

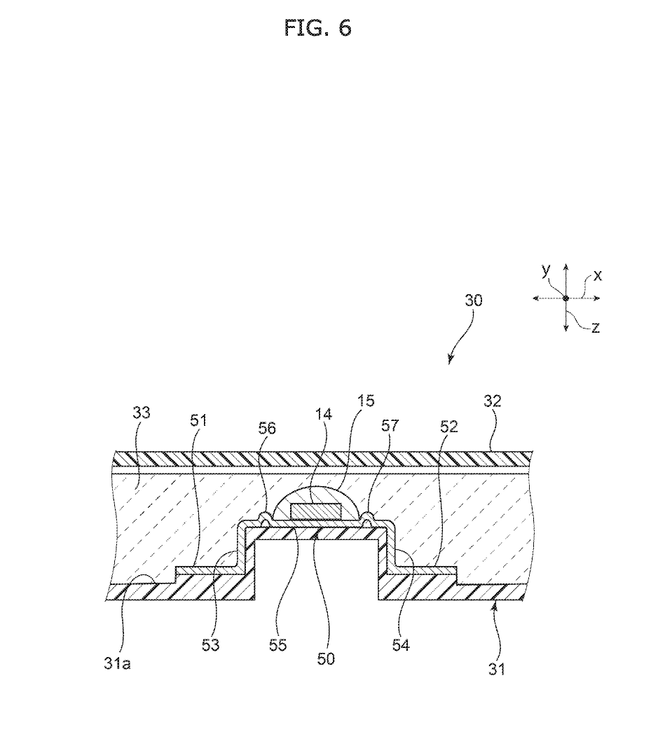

FIG. 6 is a cross-sectional view illustrating a state in which a resin is filled inside the terminal box and a cover is attached, after the connecting line is soldered to the connecting terminal. As illustrated in FIG. 6, soldering is performed with the connecting line 14 being mounted on the connecting portion 55 of the connecting terminal 50, thereby forming a soldered portion 15 to electrically connecting the connecting line 14 to the connecting terminal 50. A connecting line is electrically connected also to each of the other connecting terminals 40, 60, and 70 in the same manner as the connecting terminal 50. Subsequently, the terminal box main body 31 is filled with a filler resin 33 and the filler resin 33 is cured, and then a cover 32 is attached to the terminal box main body 31.

In such a manner as described above, it is possible to electrically connect the connecting line extending from the solar cell to the cable for external connection, in the terminal box 30.

It should be noted that, although a bifacial solar cell module is exemplified as the solar cell module 1, the present disclosure is not limited to this example.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A solar cell module terminal box to be attached to a solar cell module, the solar cell module terminal box comprising:
a connecting terminal which electrically connects a connecting line extending from the solar cell module, to a cable for external connection routed out from the solar cell module;
a terminal box main body including an attaching wall portion to which the connecting terminal is attached; and
a cover which closes the terminal box main body, wherein
the connecting terminal includes:
a base portion that is attached to the attaching wall portion;
a leg portion which extends upwardly from the base portion, away from the attaching wall portion;
a connecting portion which extends continuously from the leg portion and to which the connecting line is soldered; and
a linear protrusion disposed at each end of the connecting portion to deter solder from flowing out to the leg portion.

2. The solar cell module terminal box according to claim 1, wherein
the connecting terminal comprises a plurality of the connecting terminals, and a diode is connected between the plurality of connecting terminals.

3. The solar cell module terminal box according to claim 1, wherein
the terminal box main body includes a resin.

4. The solar cell module terminal box according to claim 1, wherein
the terminal box main body includes a through-hole through which the connecting line is routed into the terminal box main body.

5. The solar cell module terminal box according to claim 1, wherein
the solar cell module is a bifacial solar cell module.
